(19) United States
(12) Patent Application Publication
(10) Pub. No.: US 2013/0199612 A1
(43) Pub. Date: Aug. 8, 2013

(54) HYDROPHOBIC SUBSTRATE WITH ANTI-REFLECTIVE PROPERTY METHOD FOR MANUFACTURING THE SAME, AND SOLAR CELL MODULE INCLUDING THE SAME

(71) Applicant: Korea Institute of Science and Technology, Seoul (KR)

(72) Inventors: Ho Won JANG, Daegu (KR); Seok Jin YOON, Seoul (KR); Deok Ha WOO, Seoul (KR); Jin Sang KIM, Seoul (KR); Hyo Jin KWON, Daejeon (KR); Chong Yun KANG, Seoul (KR); Ji Won CHOI, Seoul (KR)

(73) Assignee: KOREA INSTITUTE OF SCIENCE AND TECHNOLOGY, Seoul (KR)

(21) Appl. No.: 13/677,733

(22) Filed: Nov. 15, 2012

(30) Foreign Application Priority Data
Feb. 6, 2012 (KR) 10-2012-0011844

(51) Int. Cl. H01L 31/0232

(52) U.S. Cl. CPC H01L 31/02327; Y10S 977/755; B82Y 30/00
USPC 136/259; 427/162; 428/141; 977/755

(57) ABSTRACT

Provided are a hydrophobic antireflective substrate, a method for manufacturing the same, and a solar cell module including the same. The hydrophobic antireflective substrate includes: a substrate; a nanostructured layer having nanostructured portions formed on the substrate and nanoporous portions formed between the nanostructured portions; and a hydrophobic coating film formed on the nanostructured portions. The method for manufacturing a hydrophobic antireflective substrate includes: forming a nanostructured layer having nanostructured portions and nanoporous portions formed between the nanostructured portions on a substrate; and forming a hydrophobic coating film on the nanostructured portions. In the hydrophobic antireflective substrate disclosed herein, a porous nanostructured layer is formed on the substrate and a hydrophobic coating film is formed on the nanostructured layer, so that the hydrophobic antireflective substrate has ultra-hydrophobic property corresponding to a large water droplet contact angle.

### CROSS-REFERENCE TO RELATED APPLICATION

This application claims priority to Korean Patent Application No. 10-2012-0011844, filed on Feb. 6, 2012, and all the benefits accruing therefrom under 35 U.S.C. §119, the contents of which in its entirety are herein incorporated by reference.

### BACKGROUND

1. Field

The present disclosure relates to a hydrophobic antireflective substrate, a method for manufacturing the same, and a solar cell module including the same. More particularly, the present disclosure relates to a hydrophobic antireflective substrate having not only ultra-hydrophobic property but also low reflectivity and high light transmission and a method for manufacturing the same. The present disclosure also relates to a solar cell module including the hydrophobic antireflective substrate.

2. Description of the Related Art

It is required for glass applied to windows for automobiles, aircrafts, buildings, or the like to have high hydrophobic property. In general, a glass surface having a large water droplet contact angle has high hydrophobic property. In addition, when a glass surface has high hydrophobic property, it is prevented from contamination or frost and may have self-cleaning property.

As a method for enhancing hydrophobic property of the surface of a substrate, such as glass, a method for surface modification including coating a hydrophobic material on the surface has been frequently used.

For example, Korean Laid-Open Patent Publication No. 10-2006-0018856 discloses a substrate having a hydrophobic surface structure formed by coating alkyl silane, etc. on the surface of a substrate, such as glass. Korean Laid-Open Patent Publication No. 10-2010-0134675 discloses hydrophobic glass obtained by coating a glass surface with chitosan. In addition, Korean Laid-Open Patent Publication No. 10-2008-0109882 discloses a method for forming a hydrophobic surface, including preparing nanoparticles, and allowing the nanoparticles to be dissolved and/or diffused onto the surface of a glass substrate.

When a glass surface is modified by the above-mentioned methods, it may have high hydrophobic property so that a water droplet contact angle of at least 60°, particularly at least 100° is obtained.

Meanwhile, many attempts have been made all over the world to increase the use of green energy sources generating no environmentally harmful gases, such as CO₂. Particularly, solar cells generating electricity by using solar light as a pollution-free energy source have been spotlighted greatly. However, commercially available solar cells still have lower power generation efficiency and higher manufacture cost per unit power generation, as compared to the existing power generation systems using fossil fuel.

To solve such problems, many studies have been conducted to improve the efficiency of a fuel cell while reducing the manufacture cost thereof. Particularly, the technology of providing a self-cleaning function to the surface (light receiving surface) of a solar cell module has been increasingly spotlighted recently.

The power generation efficiency of a solar cell may reduce by up to 25-30% due to dust or contamination on the surface of a solar cell module. Therefore, the surface of a solar cell module is cleaned periodically to prevent contamination. However, the cost required for the surface cleaning of a solar cell module is significantly higher, as compared to an increase in power generation derived from such cleaning as expressed by cost. Thus, when providing a self-cleaning function to a solar cell module surface through the ultra-hydrophobic surface formation technology, it is possible to prevent degradation of the efficiency of a solar cell caused by contamination and economic loss caused by periodic cleaning.

In general, all commercially available solar cell modules, such as silicon solar cells, compound semiconductor solar cells, organic solar cells and dye-sensitive solar cells, have surfaces made of glass. Glass protects a solar cell from external impact. Therefore, to provide a solar cell module with a self-cleaning function, a glass surface exposed to the exterior should have ultra-hydrophobic property so that water droplets may not spread on the glass surface but form spheres thereon.

However, the hydrophobic substrate according to the related art, particularly the substrate (glass) forming the surface of a solar cell module does not have high hydrophobic property, for example, corresponding to a water droplet contact angle of at least 150°. In addition, in the case of the substrate (glass) forming the surface (light receiving surface) of a solar cell module, it is required for the substrate to have not only ultra-hydrophobic property for self-cleaning but also low reflectivity (high antireflective property) for enhancing the light receiving amount (input of solar light). Furthermore, the hydrophobic substrate according to the related art does not have low reflectivity and high light transmission.

### REFERENCES OF THE RELATED ART

### Patent Document

(Patent Document 1) Korean Laid-Open Patent Publication No. 10-2006-0018856
(Patent Document 2) Korean Laid-Open Patent Publication No. 10-2010-0134675
(Patent Document 3) Korean Laid-Open Patent Publication No. 10-2008-0109882

### SUMMARY

The present disclosure is directed to providing a hydrophobic antireflective substrate having ultra-hydrophobic property corresponding to a high water droplet contact angle in combination with low reflectivity (high antireflective property) and high light transmission by forming a porous nanostructured layer on a substrate, such as glass, and forming a hydrophobic coating film on the nanostructured layer through surface modification. The present disclosure is also directed to providing a method for manufacturing the hydrophobic antireflective substrate, and a solar cell module including the hydrophobic antireflective substrate.

In one aspect, there is provided a hydrophobic antireflective substrate, including:

a substrate;

a nanostructured layer having nanostructured portions formed on the substrate and nanoporous portions formed between the nanostructured portions; and

a hydrophobic coating film formed on the nanostructured portions.

The nanostructured portions and the nanoporous portions may have a size smaller than a wavelength of visible rays. For example, the nanostructured portions and the nanoporous portions may have a size of 0.5 nm-300 nm.

According to an embodiment, the nanostructured portions may include a material having a light refractive index smaller than the light refractive index of the material forming the substrate. For example, the nanostructured portions may include at least one selected from silicon-based and fluorine-based compounds. More particularly, the nanostructured portions may include at least one selected from SiO₂, CaF₂ and MgF₂.

In addition, the nanostructured portions may have at least one shape selected from nanorods, nanocolumns, nanowires, nanoplates and nanosprings. The nanostructured portions may be formed obliquely to the substrate through glancing angle deposition.

The hydrophobic coating film may include a fluororesin. In addition, the hydrophobic coating film may have a thickness of 0.1 nm-50 nm.

In another aspect, there is provided a method for manufacturing a hydrophobic antireflective substrate, including:

forming a nanostructured layer having nanostructured portions and nanoporous portions formed between the nanostructured portions on a substrate; and

forming a hydrophobic coating film on the nanostructured portions.

Particularly, the forming a hydrophobic coating film may include coating a hydrophobic material on the nanostructured portions, and heat treating the coated hydrophobic material. The heat treatment may be carried out at a temperature of 100-300° C.

In still another aspect, there is provided a solar cell module including the hydrophobic antireflective substrate disclosed herein. Particularly, the hydrophobic antireflective substrate may form the surface of a solar cell module.

In the hydrophobic antireflective substrate disclosed herein, a nanostructured layer is formed on the substrate and a hydrophobic coating film is formed on the nanostructured layer through surface modification. Thus, the hydrophobic antireflective substrate has ultra-hydrophobic property corresponding to a large water droplet contact angle. In addition, the porous nanostructure of the surface provides a small light refractive index, and thus low reflectivity, i.e., high antireflective property, in combination with high light transmission.

More particularly, the hydrophobic antireflective substrate has ultra-hydrophobic property corresponding to a large water droplet contact angle of at least 150°, thereby providing an excellent self-cleaning function against contaminants. In addition, the hydrophobic antireflective substrate has a lower light reflectivity as compared to general glass, and realizes a light transmission of 90% or higher in a range of visible rays.

Further, when the hydrophobic antireflective substrate is applied to the surface of a solar cell module, the light receiving amount increases by virtue of low reflectivity and high light transmission, thereby increasing the power generation efficiency. In addition, the hydrophobic antireflective substrate having ultra-hydrophobic property shows an excellent self-cleaning function, and thus prevents degradation of solar cell efficiency caused by contaminants and economic loss caused by periodic cleaning.

### BRIEF DESCRIPTION OF THE DRAWINGS

The above and other aspects, features and advantages of the disclosed exemplary embodiments will be more apparent from the following detailed description taken in conjunction with the accompanying drawings in which:

FIG. 1 is a flow chart illustrating the manufacture of the hydrophobic antireflective substrate in accordance with an embodiment;

FIG. 2 shows perspective views illustrating various embodiments of the nanostructured layer forming the hydrophobic antireflective substrate in accordance with an embodiment;

FIG. 3 shows sectional views illustrating the method for forming the nanostructured layer forming the hydrophobic antireflective substrate in accordance with an embodiment;

FIG. 4 shows scanning electron microscopy (SEM) images illustrating the plane and section of the nanostructured layer formed in accordance with an embodiment;

FIG. 5 is a graph illustrating the results of water droplet contact angle measurement of the hydrophobic glass substrate manufactured in accordance with an embodiment;

FIG. 6 is a photograph showing the water droplets on the hydrophobic antireflective substrate manufactured in accordance with an embodiment;

FIG. 7 shows photographs showing the self-cleaning capability of a general glass substrate and that of the hydrophobic glass substrate manufactured in accordance with an embodiment;

FIG. 8 is a graph showing the results of light transmission measurement of the hydrophobic glass substrate manufactured in accordance with an embodiment; and

FIG. 9 is a graph showing the results of light reflectivity of a general glass substrate and that of the hydrophobic glass substrate manufactured in accordance with an embodiment.

### DETAILED DESCRIPTION OF MAIN ELEMENTS

10: substrate 20: nanostructured layer
22: nanostructured portions 24: nanoporous portions
30: hydrophobic coating film

### DETAILED DESCRIPTION

Exemplary embodiments now will be described more fully hereinafter with reference to the accompanying drawings, in which exemplary embodiments are shown.

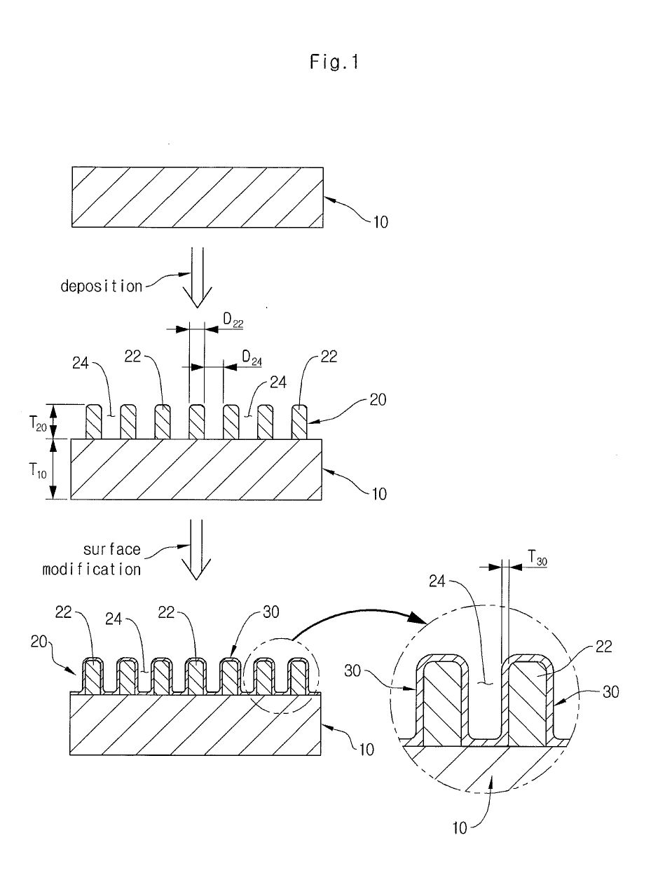

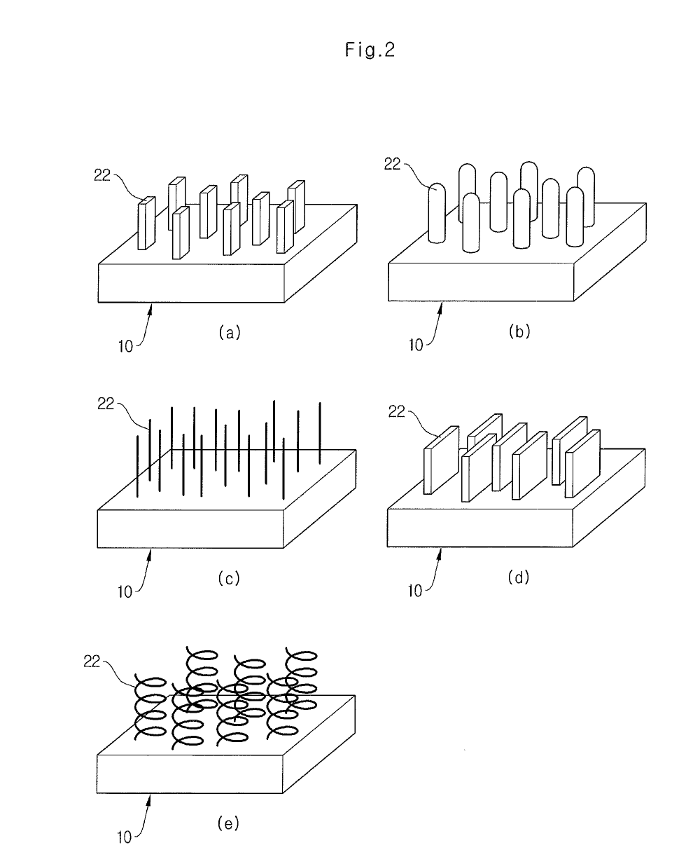

Referring to FIG. 1 and FIG. 2, the hydrophobic antireflective substrate disclosed herein includes a substrate 10, a nanostructured layer 20 formed on the substrate 10, and a hydrophobic coating film 30 formed on the nanostructured layer 20.

There is no particular limitation in the substrate 10 as long as it has supporting capability. The substrate 10 may be planar or curved. For example, the substrate 10 may be selected from a glass substrate, sapphire substrate, quartz substrate and semiconductor or ceramic substrate, or the like.

In addition, the substrate 10 may be selected from plastic substrates. Particularly, the substrate 10 may be selected from plastic substrates, including those made of polyethylene terephthalate (PET), polybutylene terephthalate (PBT), polyethylene naphthalate (PEN), polybutylene naphthalate (PBN), polyethylene (PE), polypropylene (PP) and polycarbonate (PC).

For example, the substrate 10 may be selected from constitutional parts for use in automobiles, aircrafts, buildings and solar cell modules as a surface member (protective member). In addition, the substrate 10 may be transparent, translucent or opaque. Particularly, the substrate 10 may be transparent or translucent, and more particularly, it may be transparent (e.g. a light transmission of 80% or higher).

Particularly, when used as the surface of a solar cell module, the substrate 10 may be transparent and inexpensive one. Further, the substrate 10 may have a thickness (T₁₀, see FIG. 1) of 0.05 mm-20 mm, particularly a thickness (T₁₀) of 0.1 mm-5 mm, but is not limited thereto.

The nanostructured layer 20 is formed on the substrate 10. The nanostructured layer 20 may be formed on one surface or both surfaces of the substrate 10. In FIG. 1, it is shown that the nanostructured layer 20 is formed on one surface (top surface) of the substrate.

The nanostructured layer 20 is a porous thin film having a plurality of nanostructured portions 22. As shown in FIG. 1, the nanostructured layer 20 has a plurality of nanostructured portions 22 and a plurality of nanoporous portions 24 formed between the nanostructured portions.

According to an embodiment, the above-mentioned porous nanostructured layer 20 allows the substrate to have ultra-hydrophobic property in combination with low reflectivity and high light transmission. Particularly, a hydrophobic coating film 30 is formed on the nanostructured layer 20. The nanostructured portions 22 forming the nanostructured layer 20 provides the hydrophobic coating film 30 with an increased surface area, thereby providing ultra-hydrophobic property.

In addition, the nanostructured portions 22 having a nano-scaled size (D₂₂, see FIG. 1) ensure transparency to light, thereby providing high light transmission. Further, the nanoporous portions 24 that are pores having a nano-scaled size (D₂₄, see FIG. 1) present between the nanostructured portions 22 cause a decrease in light refractive index, thereby providing low reflectivity (i.e., high antireflective property).

The nanostructured portions 22 are formed to protrude individually out of the substrate 10 so that the nanoporous portions 24 may be formed between the nanostructured portions. There is no particular limitation in the nanostructured portions, as long as they have a nano-scaled size (D₇₂).

The nanostructured portions 22 have a size (D₂₂) of 1,000 nm or less, particularly 0.1 nm-1,000 nm. More particularly, the nanostructured portions 22 may have a size (D₂₂) smaller than the wavelength (approximately 380-780 nm) of visible rays. When the nanostructured portions 22 have such a size (D₂₂) smaller than the wavelength of visible rays, it is possible to obtain increased transparency to light and high light transmission.

Particularly, the nanostructured portions 22 may have a size (D₂₂) smaller than the wavelength of visible rays, for example, a size (D₂₂) of 300 nm or less, more particularly a size (D₂₂) of 0.5 nm-300 nm in view of ultra-hydrophobic property as well as light transmission.

In addition, there is no particular limitation in the shape of the nanostructured portions 22. For example, the nanostructured portions 22 may have at least one shape selected from nanorods, nanocolumns, nanowires, nanoplates and nanosprings. More particularly, depending on the size (D₂₂) of the nanostructures, the nanostructured portions 22 may have a nanorod shape with a thickness of 100 nm-300 nm, a nanocolumn shape with a diameter (thickness) of 20 nm-100 nm, or a nanowire shape with a thickness of 0.5 nm-20 nm.

The nanostructured portions 22 may also have a nanoplate shape with a width and length of 0.5 nm-300 nm, or a nanospring shape formed by nanowires with a thickness of 0.5 nm-20 nm wound into a coil shape. FIG. 2 illustrates such various shapes of the nanostructured portions 22. Particularly, portion (a) shows nanorods, portion (b) shows nanocolumns (cylindrical columns), portion (c) shows nanowires, portion (d) shows nanoplates, and portion (e) shows nanosprings. However, the shape of the nanostructured portions 22 is not limited thereto.

Referring to FIG. 1, there is no particular limitation in the size (D₂₄) of the nanoporous portions, i.e., the distance (D₂₄) between one nanostructured portion 22 and another, as long as it is within a nanometer scale. Particularly, the nanoporous portions 24 may have a size (D₂₄) of 1,000 nm or less, more particularly 0.1 nm-1,000 nm.

Particularly, the nanoporous portions 24 may have a size (D₂₄) smaller than the wavelength of visible rays (approximately 380-780 nm). Such a size (D₂₄) of the nanoporous portions 24 smaller than the wavelength of visible rays provides a decreased light refractive index, thereby affecting light reflectivity advantageously. The nanoporous portions 24 may have a size (D₂₄) of 300 nm or less, more particularly a size (D₂₄) of 0.5 nm-300 nm in view of ultra-hydrophobic property as well as light transmission.

In addition, the nanostructured layer 20 may have a thickness (T₂₀, see FIG. 1) of 1.0 nm-20 μm. Particularly, the nanostructured layer 20 may have a thickness (T₂₀) of 100 nm-10 μm. The nanostructured layer 20 may be formed by deposition. In other words, a plurality of nanostructured portions 22 may be formed on the substrate 10 by deposition. For example, the nanostructured portions 22 may be formed by sputtering, electron beam deposition, chemical vapor deposition or wet deposition processes.

There is no particular limitation in the material forming the nanostructured layer 20. In other words, the nanostructured portions 22 may be formed of various materials. Particularly, the nanostructured portions 22 may include at least one selected from silicon-based compounds and fluorine-based compounds.

As used herein, the silicon-based compound means a compound having Si in its molecule, and may be selected from SiO₂, SiOC, SiON, SiOCN and Si₃N₄. The fluorine-based compound means a compound having F in its molecule, and may be selected from CaF₂ and MgF₂.

According to some embodiments, the nanostructured portions 22 may be formed of a material having a light refractive index equal to or smaller than the light refractive index of the material forming the substrate 10. In this case, it is possible to obtain a decreased light refractive index and low reflectivity (i.e., high antireflective property). For example, when the substrate 10 is made of glass, the nanostructured portions 22 may be exclusively formed of SiO₂ that is a main ingredient of glass, or may be formed of at least one selected from CaF₂ and MgF₂ having a smaller light refractive index as compared to glass.

Particularly, the nanostructured portions 22 may be formed of a material having a smaller light refractive index as compared to the material forming the substrate 10. For example, when the substrate 10 is made of glass, the nanostructured portions 22 may be formed of at least one selected from CaF₂ and Mg F₂.

Then, a hydrophobic coating film 30 is formed on the nanostructured layer 20. The hydrophobic coating film 30 is coated in such a manner that it covers at least the surface of the nanostructured portions 22. Particularly, as shown in FIG. 1, the coating film is also formed on the substrate 10 between one nanostructured portions 22 and another.

The hydrophobic coating film 30 is formed by coating a hydrophobic material, and the hydrophobic material is not particularly limited as long as it has hydrophobic property. For example, the hydrophobic material may be selected from organic compounds, inorganic compounds and organic/inorganic composites. More particularly, the hydrophobic material may be selected from at least one organic compound selected from fluororesins, alkyl silane compounds and fluorosilane compounds.

More particularly, the hydrophobic material may include a fluororesin among the above-listed compounds. Although there is no particular limitation in the fluororesin, as long as it has F in its molecule. For example, the fluororesin may be selected from polytetrafluoroethylene (PTFE), perfluoroalkoxy resins (PFA), tetrafluoroethylene-perfluoroalkoxyethylene copolymer resins (TFE-PFA), tetrafluoroethylene resins (TFE), hexafluoropropylene resins (HFP), tetrafluoroethylene-hexafluoropropylene copolymer resins (TFE-HFP), ethylene-tetrafluoroethylene resins (ETFE), polychlorotrifluoroethylene (PCTFE), ethylene-chlorotrifluoroethylene resins (ECTFE), polyvinylodene fluoride (PVDF), polyvinyl fluoride (PVF), or the like.

In addition, there is no particular limitation in the thickness (T₃₀) of the hydrophobic coating film 30. The hydrophobic coating film 30 may have different thicknesses (T₃₀) depending on particular use. For example, in the case of a product (e.g. a solar cell module) requiring ultra-hydrophobic property in combination with light transmission, the hydrophobic coating film 30 may have a thickness (T₃₀) of 0.1 nm-50 nm. When the hydrophobic coating film 30 has a thickness (T₃₀) less than 0.1 nm, it is not possible to obtain sufficient ultra-hydrophobic property. On the other hand, when the hydrophobic coating film 30 has a thickness (T₃₀) greater than 50 nm, it is not possible to obtain high light transmission. Further, in the case of a fluororesin, a thickness (T₃₀) of 9 nm or more is favorable to ultra-hydrophobic property. Thus, the hydrophobic coating film 30 formed of a fluororesin may have a thickness (T₃₀) of 9 nm-50 nm.

The hydrophobic antireflective substrate as described above may be obtained by various methods with no particular limitation. For example, the hydrophobic antireflective substrate may be obtained by the method as described hereinafter. The method for manufacturing a hydrophobic antireflective substrate according to an embodiment will now be described.

The method for manufacturing a hydrophobic antireflective substrate includes forming a nanostructured layer 20 on a substrate 10, and forming a hydrophobic coating film 30 on the nanostructured layer 20. The materials and types forming the substrate 10, the nanostructured layer 20 and the hydrophobic coating film 30 are the same as described above.

Particularly, the substrate 10 may be selected from a glass substrate, sapphire substrate, quartz substrate, semiconductor or ceramic substrate, and a plastic substrate. Such substrates may be transparent.

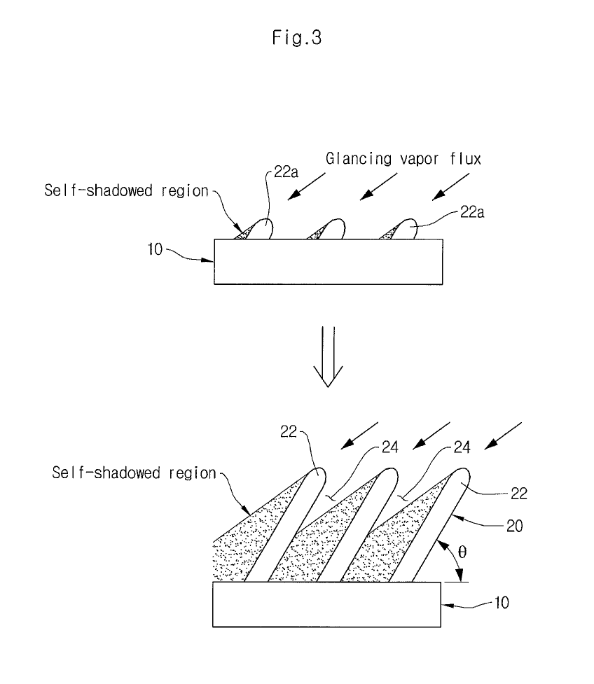

In addition, the nanostructured layer 20 may be formed by deposition of at least one selected from silicon-based compounds and fluorine-based compounds. As mentioned above, the deposition may be carried out by sputtering deposition, electron beam deposition, chemical vapor deposition or wet deposition processes. The nanostructured layer 20 includes a plurality of nanostructured portions 22 formed on the substrate 10, and a plurality of nanoporous portions 24 formed between the nanoporous portions 22. Various methods for forming such a porous nanostructured layer 20 may be used. Particularly, the nanostructured layer 20 may be formed by glancing angle deposition as described hereinafter with reference to FIG. 3.

Referring to FIG. 3, a target (constitutional material source, for example CaF₂, MgF₂ or the like) for the nanostructured portions 22 is deposited on the substrate 10, wherein the vapor flux of the target (constitutional material source) is allowed to be deposited obliquely to the substrate 10 at a predetermined angle, thereby forming the nuclei 22a of nanostructured portions 22. Then, deposition is carried out continuously to allow the targets to grow obliquely onto the nuclei 22a, thereby forming the nanostructured portions 22. Due to a so-called self-shadowing effect, nanoporous portions 24 are formed between the nanostructured portions 22. In other words, at the self-shadowed regions shown in FIG. 3, the target flux may not be deposited due to the shadowing caused by the columnar nanostructured portions 22, so that the nanoporous portions 24 are formed at the corresponding regions.

In addition, for the purpose of glancing deposition of the flux of target (constitutional material source) with a predetermined angle, deposition may be carried out while the substrate 10 and the target are maintained at an angle of 90° or 180° to each other, particularly at an angle less than 90°. For example, during the deposition, the substrate 10 and the target may be maintained at an angle of 60°-89°. In this manner, the nanostructured portions 22 may be formed on the substrate 10 while forming an angle (θ) less than 90°, for example at an angle (θ) of 60°-89° therebetween.

After the nanostructured layer 20 is formed through the deposition as described above, the nanostructured layer 20 is imparted with ultra-hydrophobic property through surface modification. In other words, a hydrophobic coating film 30 is formed at least on the surface of the nanostructured portions 22. Herein, the forming the hydrophobic coating film 30 may include coating a hydrophobic material on the nanostructured portions 22 and heat treating the coated hydrophobic material.

Particular examples of the hydrophobic material are the same as described above. There is no particular limitation in the hydrophobic material as long as it has hydrophobic property. For example, the hydrophobic material may be selected from organic compounds, inorganic compounds and organic/inorganic composites. Particularly, the hydrophobic material includes organic compounds, such as the above-listed fluororesins.

In addition, the hydrophobic material may be coated after diluted (mixed) in (with) a solvent. There is no particular limitation in the solvent, as long as it performs dilution of the hydrophobic material (e.g. fluororesin) so as to provide a viscosity that allows coating. For example, the solvent may be at least one organic solvent selected from alcohols, glycols, ketones and foramides. Particularly, at least one solvent selected from methanol, ethanol, isopropanol, methylene glycol, ethylene glycol, methyl ethyl ketone (MEK) and dimethylformamide (DMF) may be used. The solvent may be used in an amount of 50-300 parts by weight based on 100 parts by weight of the hydrophobic material. When the solvent is used in an amount less than 50 parts by weight, coating workability may be degraded due to high viscosity. On the other hand, when the solvent is used in an amount greater than 300 parts by weight, an excessively long curing (drying) time is required undesirably.

Further, there is no particular limitation in the coating method and number of coating times. For example, the hydrophobic coating material may be coated at least once by using at least one coating method selected from dip coating, spin coating, spray coating, gravure coating and screen printing.

After coating the hydrophobic material as described above, heat treatment is carried out to perform curing of the hydrophobic material. The heat treatment may be carried out at a temperature of 100-300° C. in view of improvement of curing stability. In other words, a heat treatment temperature less than 100° C. makes it difficult to perform curing of a hydrophobic material, such as a fluororesin. On the other hand, a heat treatment temperature higher than 300° C. may adversely affect the nanostructured portions 22 (e.g. cracking).

As described above, the hydrophobic antireflective substrate disclosed herein has a nanostructured layer 20 and a hydrophobic coating film 30 formed on the nanostructured layer 20, and thus shows excellent hydrophobic property. For example, the hydrophobic antireflective substrate has ultra-hydrophobic property corresponding to a water droplet contact angle of at least 150°. Therefore, it has an excellent self-cleaning function against contaminants. In addition, the porous surface nanostructure provides a small light refractive index, and thus low reflectivity, i.e., high antireflective property, in combination with high light transmission.

For example, the hydrophobic antireflective substrate has significantly lower light reflectivity as compared to general glass, and a light transmission of 90% or higher in a region of visible rays. In addition, the hydrophobic antireflective substrate having the above-mentioned surface nanostructure has not only self-cleaning property but also anti-dew condensation, antistatic and anticorrosive properties. It also has high light transmission to visible rays as well as IR- and UV-shielding properties.

The hydrophobic antireflective substrate disclosed herein may be applied to various industrial fields. For example, it may be applied as a window or partition in automobiles, aircrafts and buildings. Particularly, the hydrophobic antireflective substrate may be applied to products, such as solar cell modules, requiring ultra-hydrophobic property in addition to low reflectivity and high light transmission. The solar cell module according to an embodiment will now be described.

The solar cell module disclosed herein may be formed in a conventional manner. The solar cell module may include: a protective member protecting a solar cell while being exposed to the exterior to receive the solar light; a charging layer formed at the bottom of the protective member; a plurality of solar cells embedded in the charging layer; and a back sheet attached to the bottom of the charging layer. There is no particular limitation in the types of solar cell. The solar cell may be a silicon solar cell, compound semiconductor solar cell, organic solar cell and a dye sensitive solar cell.

The solar cell module disclosed herein includes the hydrophobic antireflective substrate disclosed herein. Particularly, the protective member may include the hydrophobic antireflective substrate disclosed herein. In other words, the hydrophobic antireflective substrate disclosed herein may form the surface (light receiving surface) of the solar cell module.

Therefore, the solar cell module disclosed herein has an excellent self-cleaning function by virtue of the ultra-hydrophobic property of the hydrophobic antireflective substrate, thereby preventing degradation of solar cell efficiency caused by contaminants, and economic loss caused by periodical cleaning. Further, the solar cell module provides increased power generation efficiency by virtue of low reflectivity and high light transmission.

The examples and experiments will now be described. The following examples and experiments are for illustrative purposes only and not intended to limit the scope of the present disclosure.

### Examples 1-5

### Deposition of Nanostructured Layer

First, a 2.0 mm-transparent glass substrate is installed in an electron beam deposition system. Next, CaF₂ is deposited as a nanostructured layer on the glass substrate. When depositing the nanostructured layer (CaF₂), the CaF₂ source and the glass substrate are maintained at an angle of about 85° and then deposition is carried out so that CaF₂ is deposited with a glancing angle in a nanowire shape. In addition, nanostructured layers (CaF₂) different in thickness are used in different Examples. In other words, the nanostructured layer has the thickness (length of CaF₂ nanowires) as follows: 200 nm (Example 1), 500 nm (Example 2), 750 nm (Example 3), 1.0 μm (Example 4) and 1.5 μm (Example 5).

<Surface Modification>

Then, the glass substrate on which the nanostructured layer (CaF₂) is formed according to each Example is subjected to surface modification with a fluororesin. Particularly, the glass substrate on which the nanostructured layer (CaF₂) is formed is dipped into a solution containing a fluororesin (PTFE) so that the surface of the nanostructured layer (CaF₂) is coated with the fluororesin (PTFE). After the coated substrate is introduced to an oven, it is heat treated at a temperature of 200° C. to cure (stabilize) the fluororesin (PTFE). In this manner, a hydrophobic glass substrate, including a glass substrate, a nanostructured layer of CaF₂ nanowires deposited on the glass substrate, and a fluororesin (PTFE) coating film formed on the nanostructured layer, is obtained.

### Comparative Example 1

Example 1 is repeated except that no nanostructured layer is formed and only the fluororesin (PTFE) coating film is formed. Particularly, after the glass substrate is dipped into a solution containing a fluororesin (PTFE), it is heat treated under the same conditions. In this manner, a hydrophobic glass substrate, including a glass substrate, and a fluororesin (PTFE) coating film formed directly on the glass substrate without any nanostructured layer, is obtained.

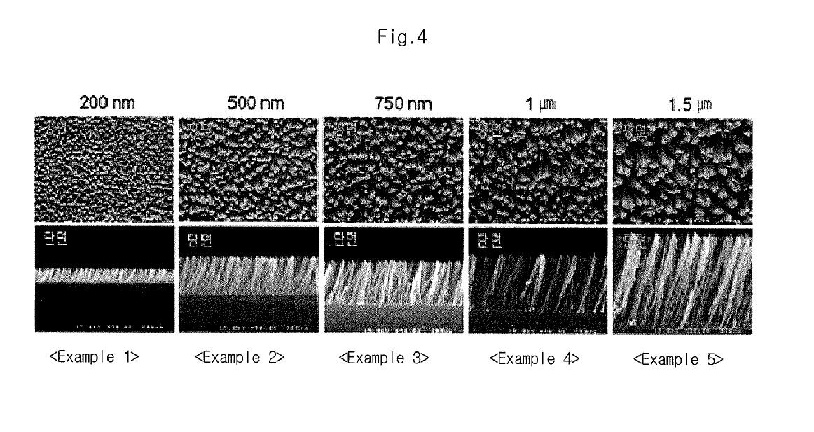

FIG. 4 shows scanning electron microscopy (SEM) images illustrating the plane and section of the nanostructured layer having a different thickness according to each Example. As shown in FIG. 4, the nanostructured layer having a nanowire shape is also provided with a nanowire size (wire thickness) and a pore size (distance between nanowires) of several nanometers or less, which are smaller than the wavelength of visible rays.

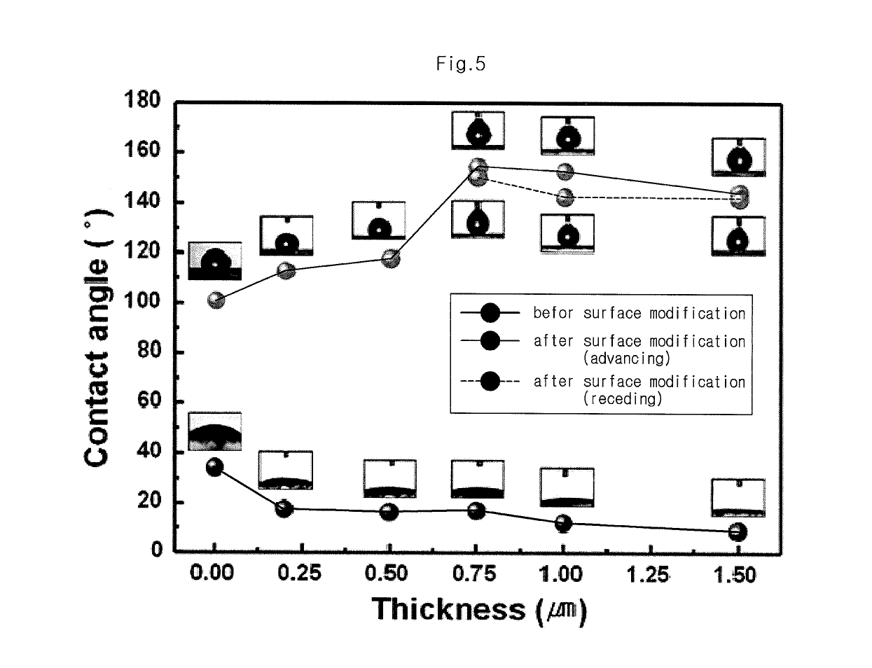

In addition, FIG. 5 is a graph illustrating the results of water droplet contact angle measurement of the hydrophobic glass substrates according to Examples 1-5 and Comparative Example 1. In FIG. 5, both the results before surface modification (before fluororesin coating) and the results after surface modification (after fluororesin coating) are shown.

As shown in FIG. 5, before surface modification (before fluororesin coating), the glass surface shows hydrophilic property (water contact angle of 30° or less). However, after surface modification (after fluororesin coating), it is shown that the glass surface is modified into hydrophobic one (water contact angle of 100° or more).

In addition, it can be seen that hydrophobic property depends on the presence of a nanostructured layer and the thickness thereof. In other words, Comparative Example 1 having a fluororesin coating film without any nanostructured layer shows a contact angle of about 100°. On the contrary, Examples in which a fluororesin coating film is formed after a nanostructured layer is formed as disclosed herein shows high hydrophobic property corresponding to a contact angle of 110° or more. It can be seen that as the thickness of the nanostructured layer increases, the contact angle also increases. Particularly, when the nanostructured layer has a thickness of 750 nm (Example 3), the contact angle is 150° or more after surface modification, and the difference between advancing contact angle and receding contact angle is 5° or less. This demonstrates that an ultra-hydrophobic surface is formed.

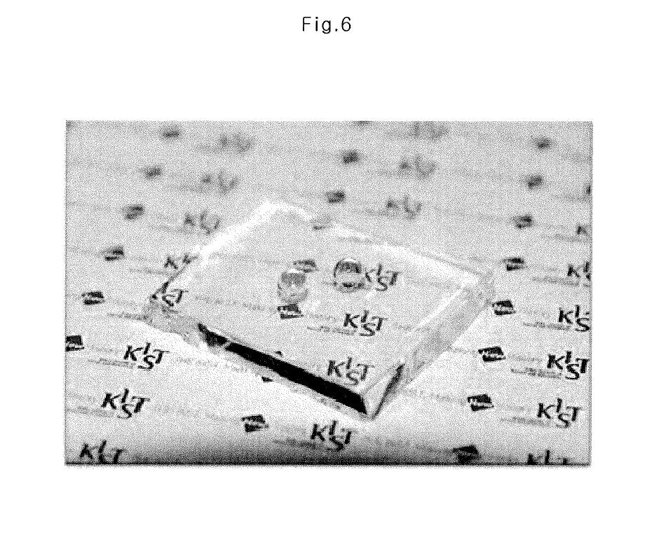

FIG. 6 is a photograph showing the water droplets on the hydrophobic glass substrate manufactured in accordance with Example 3. As shown in FIG. 6, when water droplets are dropped onto the surface of the hydrophobic glass substrate, they maintain a completely spherical shape, suggesting that the hydrophobic glass substrate has ultra-hydrophobic property. It can be also seen that the hydrophobic glass substrate is transparent.

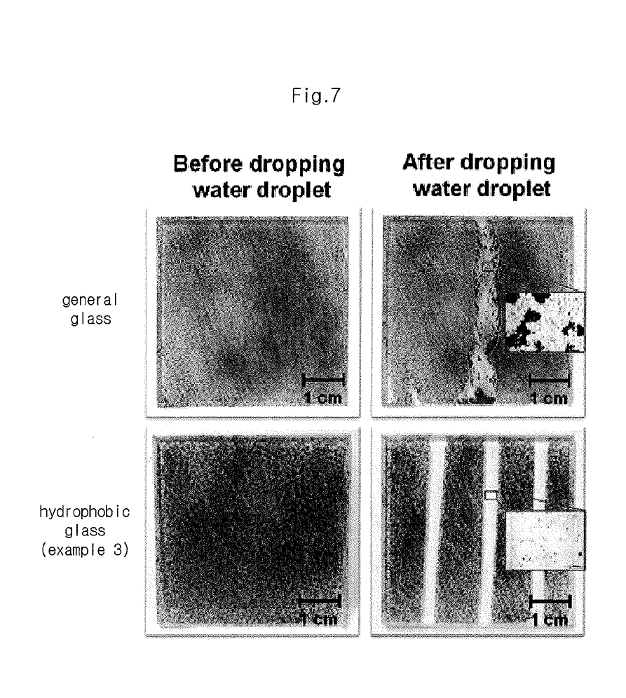

FIG. 7 shows photographs illustrating the self-cleaning capability of a general glass substrate and that of the hydrophobic glass substrate manufactured in accordance with Example 3. The results before dropping water droplets are shown together with the results after dropping water droplets. Iron oxide powder with a size of 5 μm or less is dispersed uniformly onto the surface of the general glass substrate and that of the hydrophobic glass substrate according to Example 3, and water drops are dropped thereon for the purpose of comparison of cleaning ability to iron oxide powder. Herein, each glass substrate is maintained at an angle of 45° to the ground so that water droplets flow down naturally on the glass surface.

As shown in FIG. 7, in the case of the general glass substrate, iron oxide powder is not removed even after water droplets completely flow down. Rather, iron powder causes agglomeration, thereby making the surface more opaque. In addition, when water droplets are dropped on the general glass substrate, the flow rate is as slow as 0.167 cm/s.

On the contrary, in the case of the hydrophobic glass substrate according to Example 3, iron oxide powder is removed effectively from the surface. When water droplets are dropped, the flow rate is as high as 11.3 cm/s. This demonstrates that the hydrophobic glass substrate has higher self-cleaning ability as compared to the general glass substrate.

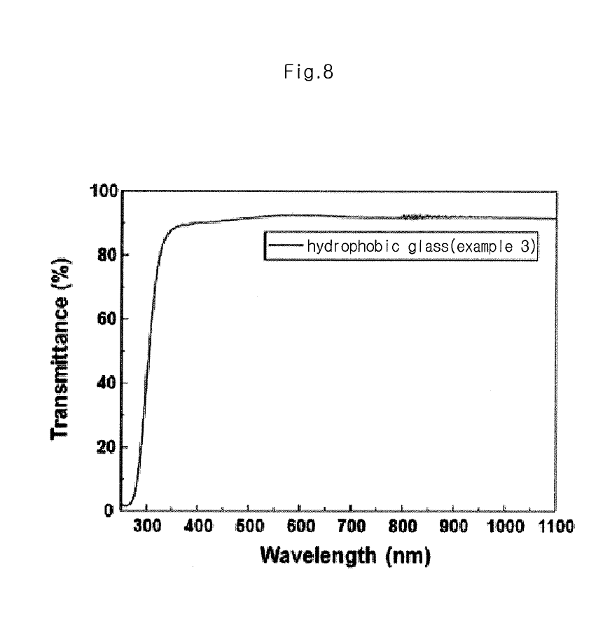

FIG. 8 is a graph showing the results of light transmission measurement of the hydrophobic glass substrate manufactured in accordance with Example 3. The total transmission is measured when the light incidence is made in perpendicular to the glass substrate. As shown in FIG. 8, a light transmission is 90% or higher in a range of visible rays. It can be seen that the hydrophobic glass substrate has high light transmission.

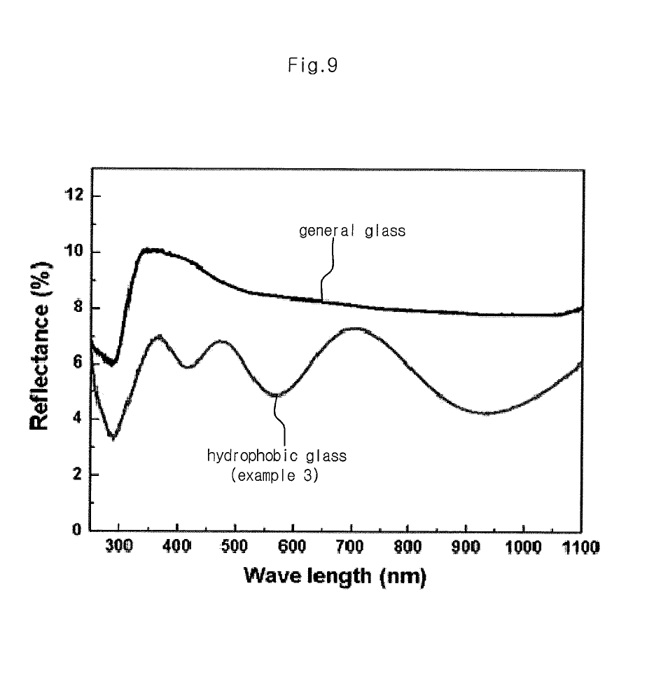

FIG. 9 is a graph showing the results of light reflectivity of a general glass substrate and that of the hydrophobic glass substrate manufactured in accordance with Example 3. The total light reflectivity is measured when the light incidence is made at an angle of 8° to the glass surface. As shown in FIG. 9, the hydrophobic glass substrate according to Example 3 has a total reflectivity of 6% or less in a range of visible rays. In other words, the hydrophobic glass substrate has a reflectivity significantly lower than the reflectivity of the general glass substrate. This demonstrates that the hydrophobic glass substrate has excellent antireflective property.

As can be seen from the foregoing, the hydrophobic antireflective substrate having a porous surface nanostructure has ultra-hydrophobic property corresponding to a water droplet contact angle of at least 150°, thereby providing an excellent self-cleaning function. The hydrophobic antireflective substrate also has a reflectivity significantly lower than the reflectivity of general glass, in combination with a high light transmission of 90% or more.

While the exemplary embodiments have been shown and described, it will be understood by those skilled in the art that various changes in form and details may be made thereto without departing from the spirit and scope of the present disclosure as defined by the appended claims.

What is claimed is:

1. A hydrophobic antireflective substrate, comprising:
a substrate;
a nanostructured layer having nanostructured portions formed on the substrate and nanoporous portions formed between the nanostructured portions; and
a hydrophobic coating film formed on the nanostructured portions.

2. The hydrophobic antireflective substrate according to claim 1, wherein the nanostructured portions and the nanoporous portions have a size smaller than a wavelength of visible rays.

3. The hydrophobic antireflective substrate according to claim 1, wherein the nanostructured portions and the nanoporous portions have a size of 0.5 nm-300 nm.

4. The hydrophobic antireflective substrate according to claim 1, wherein the nanostructured portions comprise at least one selected from silicon-based compounds and fluorine-based compounds.

5. The hydrophobic antireflective substrate according to claim 1, wherein the nanostructured portions comprise a material having a light refractive index smaller than the light refractive index of the material forming the substrate.

6. The hydrophobic antireflective substrate according to claim 1, wherein the nanostructured portions comprise at least one selected from SiO₂, CaF₂ and MgF₂.

7. The hydrophobic antireflective substrate according to claim 1, wherein the nanostructured portions have at least one shape selected from nanorods, nanocolumns, nanowires, nanoplates and nanosprings.

8. The hydrophobic antireflective substrate according to claim 1, wherein the nanostructured portions are formed obliquely to the substrate.

9. The hydrophobic antireflective substrate according to claim 1, wherein the nanostructured layer has a thickness of 1.0 nm-20 μm.

10. The hydrophobic antireflective substrate according to claim 1, wherein the hydrophobic coating film comprises a fluororesin.

11. The hydrophobic antireflective substrate according to claim 1, wherein the hydrophobic coating film has a thickness of 0.1 nm-50 nm.

12. A method for manufacturing a hydrophobic antireflective substrate, comprising:
forming a nanostructured layer having nanostructured portions and nanoporous portions formed between the nanostructured portions on a substrate; and
forming a hydrophobic coating film on the nanostructured portions.

13. The method for manufacturing a hydrophobic antireflective substrate according to claim 12, wherein said forming a nanostructured layer comprises depositing at least one selected from silicon-based compounds and fluorine-based compounds on the substrate.

14. The method for manufacturing a hydrophobic antireflective substrate according to claim 12, wherein said forming a nanostructured layer comprises forming the nanostructured portions obliquely to the substrate.

15. The method for manufacturing a hydrophobic antireflective substrate according to claim 12, wherein said forming a hydrophobic coating film comprises coating a hydrophobic material on the nanostructured portions, and heat treating the coated hydrophobic material.

16. The method for manufacturing a hydrophobic antireflective substrate according to claim 15, wherein the hydrophobic material comprises a fluororesin.

17. The method for manufacturing a hydrophobic antireflective substrate according to claim 15, wherein the heat treatment is carried out at a temperature of 100-300° C.

18. A solar cell module comprising the hydrophobic antireflective substrate as defined in claim 1.
